(19) United States
(12) Patent Application Publication
(10) Pub. No.: US 2024/0224484 A1
(43) Pub. Date: Jul. 4, 2024

(54) COMPONENT MOUNTING MACHINE

(71) Applicant: FUJI CORPORATION, Chiryu (JP)

(72) Inventors: Hiroyuki KAGOSHIMA, Kariya-shi (JP); Tadashi KUMAGAI, Okazaki-shi (JP)

(73) Assignee: FUJI CORPORATION, Chiryu (JP)

(21) Appl. No.: 18/558,231

(22) PCT Filed: May 24, 2021
(86) PCT No.: PCT/JP2021/019539

§ 371 Date: Oct. 31, 2023

(51) Int. Cl. H05K 13/04

(52) U.S. Cl. CPC H05K 13/0408

(57) ABSTRACT

A component mounting machine includes a head configured to pick up the component, a pair of first axis linear guides configured to extend in a first axis direction, a beam member made of carbon fiber reinforced plastic or aramid fiber reinforced plastic in a rectangular tubular shape to extend in a second axis direction intersecting the first axis, having both end portions bridged between the pair of first axis linear guides, and configured to move in the first axis direction, and a pair of second axis linear guides disposed on the beam member to extend in the second axis direction and configured to guide the head movably in the second axis direction.

### TECHNICAL FIELD

The present description discloses a component mounting machine.

### BACKGROUND ART

In the conventional art, there has been proposed a component mounting machine including a head on which a component is mounted, a rail that slidably guides the head in an X-axis direction, an X beam that extends in the X-axis direction and has the rail attached thereto and is made of aluminum or an aluminum alloy, a Y beam that slidably guides the X beam in a Y-axis direction, and a reinforcing member that is made of carbon fiber reinforced plastic or aramid fiber reinforced plastic and is attached to the X beam (for example, refer to Patent Literature 1).

### PATENT LITERATURE

Patent Literature 1: JP-A-2012-129317

### SUMMARY OF THE INVENTION

### Technical Problem

In the component mounting machine described above, the weight reduction of the X beam is insufficient, and there is a limit to the high-speed movement of the X beam. In addition, it is difficult to process members such as carbon fiber reinforced plastic, and if a shape thereof becomes complicated, the manufacturing cost increases.

A main object of the present disclosure is to provide a component mounting machine that is capable of reducing the weight of a beam member and reducing the manufacturing cost.

### Solution to Problem

The present disclosure employs the following means in order to achieve the above-described main object.

A summary of a component mounting machine of the present disclosure is a component mounting machine for mounting a component that includes a head configured to pick up the component, a pair of first axis linear guides configured to extend in a first axis direction, a beam member made of carbon fiber reinforced plastic or aramid fiber reinforced plastic in a rectangular tubular shape to extend in a second axis direction intersecting the first axis, having both end portions bridged between the pair of first axis linear guides, and configured to move in the first axis direction, and a pair of second axis linear guides disposed on the beam member to extend in the second axis direction and configured to guide the head movably in the second axis direction.

In the component mounting machine of the present disclosure, the beam member is made of carbon fiber reinforced plastic or aramid fiber reinforced plastic in a rectangular tubular shape. Accordingly, weight reduction can be achieved while ensuring rigidity. As a result, it is possible to further speed up the movement of the head. Furthermore, since the simple shape facilitates processing, the manufacturing cost can be reduced.

### BRIEF DESCRIPTION OF DRAWINGS

FIG. 1 is a perspective view of a component mounting machine of the present embodiment.

FIG. 2 is a top view of the component mounting machine of the present embodiment.

FIG. 3 is an external perspective view of a beam member.

FIG. 4 is an external perspective view of a head and the beam member.

FIG. 5 is a partial enlarged view of an X-axis linear scale and a Y-axis linear scale.

FIG. 6 is an external perspective view of an X-axis moving device.

FIG. 7 is a cross-sectional view of an X-axis cooling device.

FIG. 8 is an external perspective view of a Y-axis moving device and a Y-axis cooling device.

FIG. 9 is an exploded perspective view of the Y-axis moving device and the Y-axis cooling device.

FIG. 10 is an external perspective view of a Y-axis mover.

FIG. 11 is a cross-sectional view of the Y-axis cooling device.

### DESCRIPTION OF EMBODIMENTS

Next, an embodiment of the present disclosure will be described with reference to the drawings.

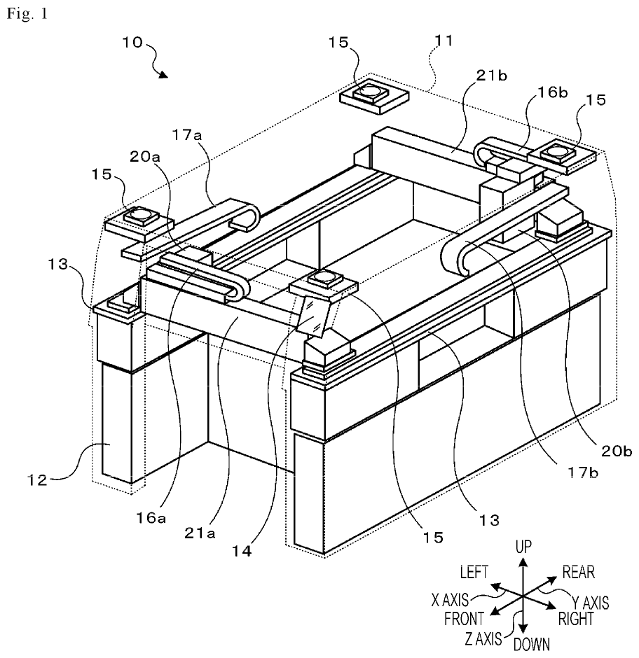

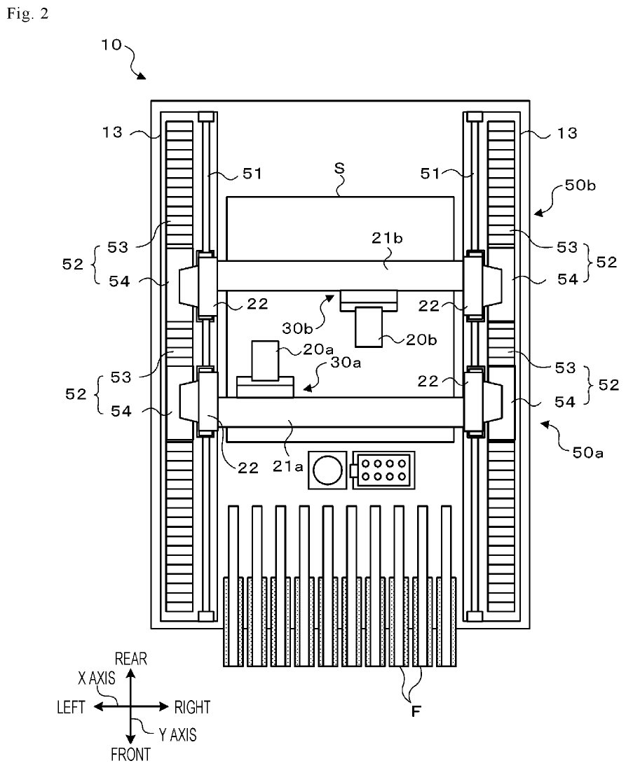

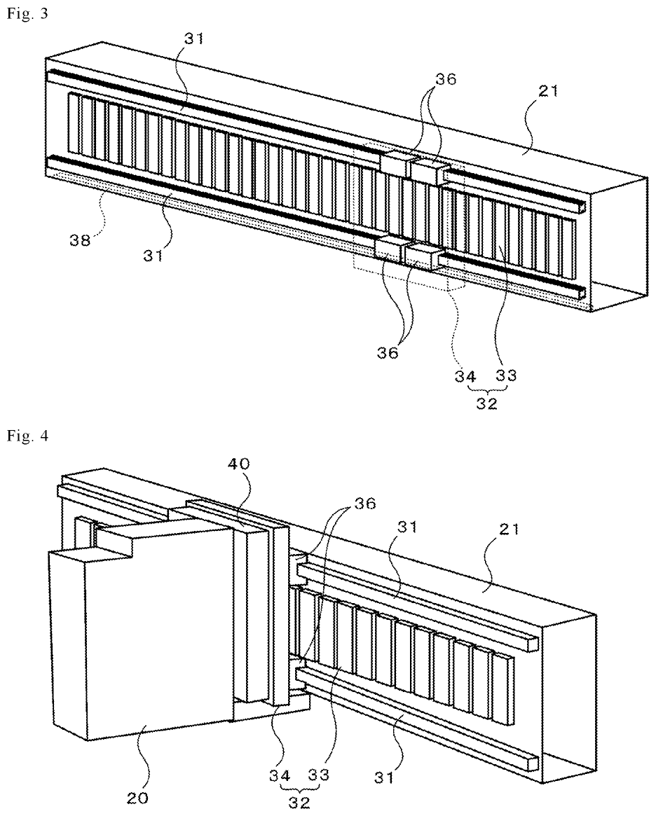

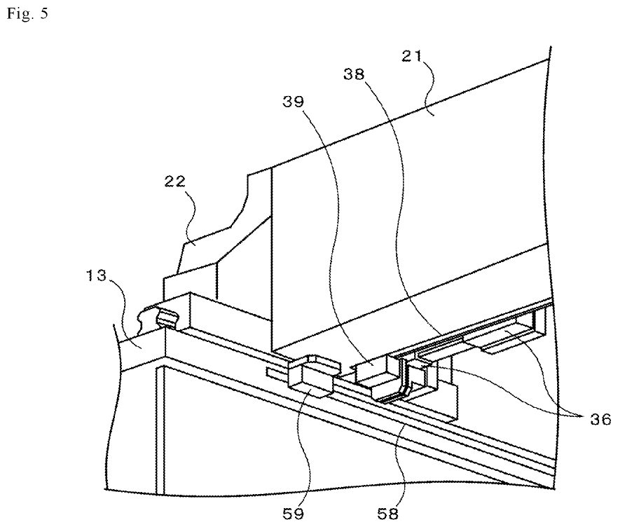

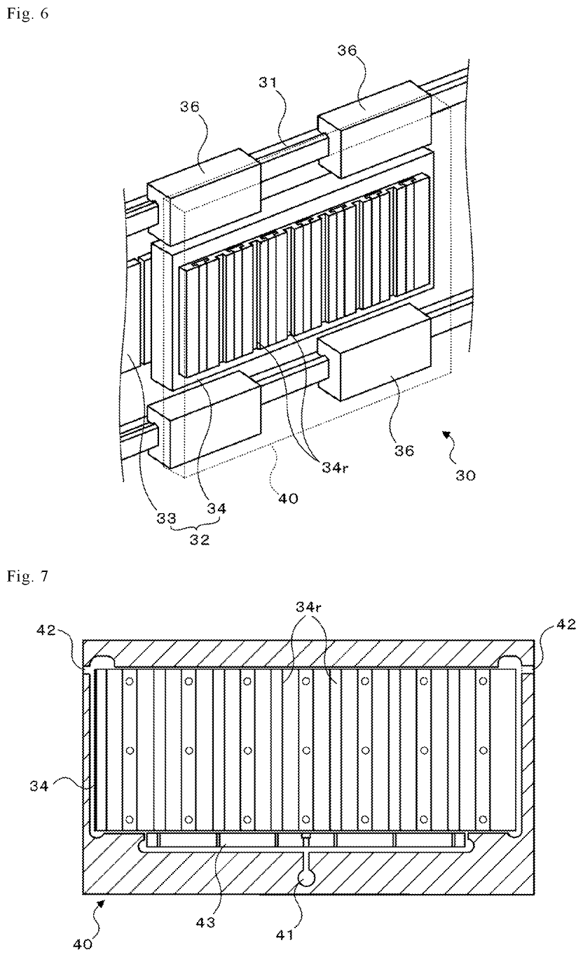

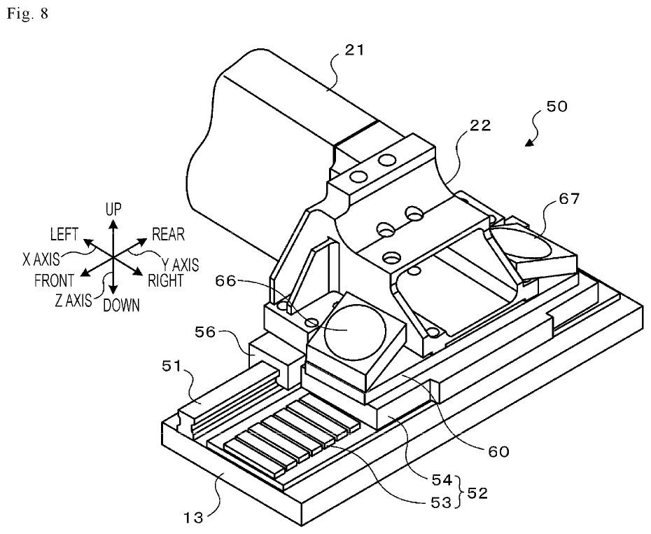

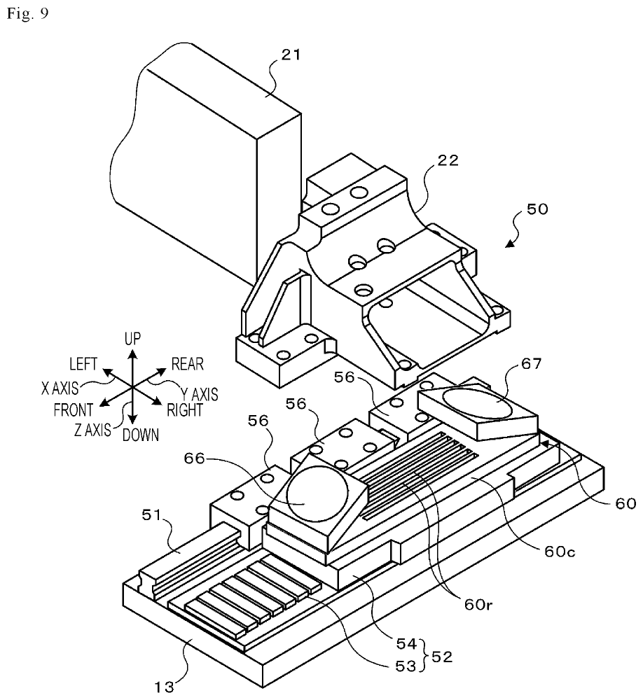

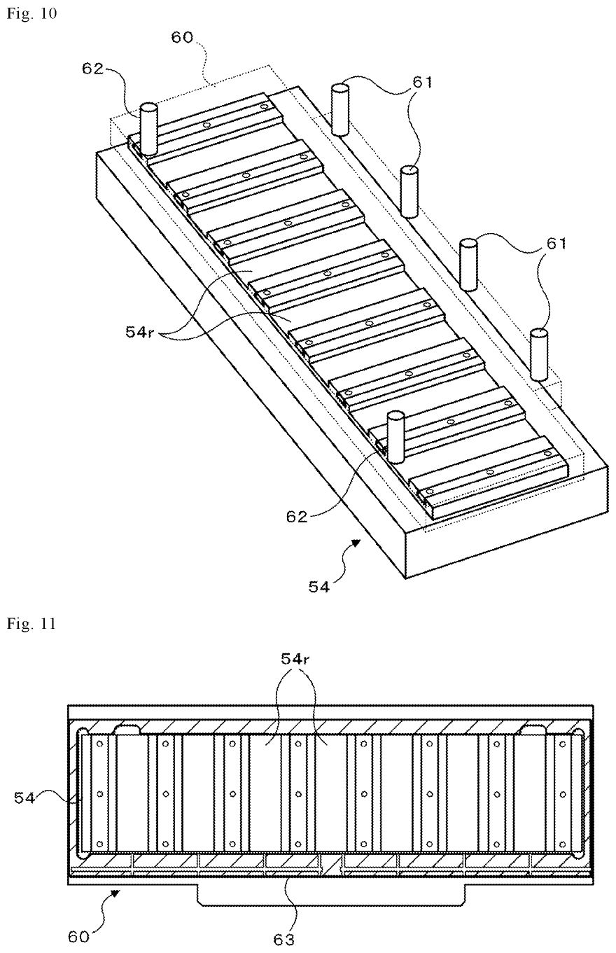

FIG. 1 is a perspective view of component mounting machine 10 of the present embodiment. FIG. 2 is a top view of component mounting machine 10 of the present embodiment. FIG. 3 is an external perspective view of beam member 21. FIG. 4 is an external perspective view of head 20 and beam member 21. FIG. 5 is a partial enlarged view of X-axis linear scale 38 and Y-axis linear scale 58. FIG. 6 is an external perspective view of X-axis moving device 30. FIG. 7 is a cross-sectional view of X-axis cooling device 40. FIG. 8 is an external perspective view of Y-axis moving device 50 and Y-axis cooling device 60. FIG. 9 is an exploded perspective view of Y-axis moving device 50 and Y-axis cooling device 60. FIG. 10 is a perspective view of Y-axis mover 54. FIG. 11 is a cross-sectional view of Y-axis cooling device 60. In FIG. 1, a left-right direction is defined as an X-axis (second axis) direction, a front-rear direction is defined as a Y-axis (first axis) direction, and an up-down direction is defined as a Z-axis direction.

As illustrated in FIGS. 1 and 2, component mounting machine 10 of the present embodiment picks up a component supplied from feeder F and mounts the component on board S. Component mounting machine 10 includes base 12, a board conveyance device (not illustrated), first and second heads 20a and 20b, first and second beam members 21a and 21b, first and second X-axis moving devices 30a and 30b, and first and second Y-axis moving devices 50a and 50b. These are accommodated in housing 11. Strip-shaped support table 13 extending in the front-rear direction is provided on both left and right sides of an upper stage of base 12. In addition, operation panel 14, which is operated by an operator and can display various kinds of information, is installed on the front surface of housing 11. First head 20a and second head 20b may be simply referred to as head 20. First beam member 21a and second beam member 21b may be simply referred to as beam member 21. First X-axis moving device 30a and second X-axis moving device 30b may be simply referred to as X-axis moving device 30. First Y-axis moving device 50a and second Y-axis moving device 50b may be simply referred to as Y-axis moving device 50.

The board conveyance device has a pair of front and rear conveyor belts and a motor that drives the conveyor belts to rotate. The board conveyance device conveys board S on the conveyor belt from left to right by driving the conveyor belt by the motor. The board conveyance device may include multiple lanes for conveying board S in a width direction orthogonal to the board conveyance direction. In addition, the board conveyance device may convey board S such that multiple boards S are arranged in the board conveyance direction.

First and second heads 20a and 20b have nozzles for picking up components. As illustrated in FIGS. 1 and 2, first head 20a is supported by first beam member 21a to be movable to the left-right direction (X axis). Second head 20b is supported by second beam member 21b to be movable to the left-right direction (X axis).

First and second beam members 21a and 21b (beam members 21) are long members extending in the left-right direction (X axis), are bridged over pair of left and right iron Y-axis linear guides 51 (guide rails), which are disposed parallel to each other and are shared with each other, and are movable in the front-rear direction (Y axis) along pair of Y-axis linear guides 51. As illustrated in FIGS. 2 to 4, first and second beam members 21a and 21b are made of carbon fiber reinforced plastic (CFRP) in a rectangular tubular shape, and pair of upper and lower iron X-axis linear guides 31 (guide rails) extending in parallel to each other in the left-right direction are joined to side surfaces facing each other. First and second beam members 21a and 21b may be made of aramid fiber reinforced plastic (AFRP). Pair of upper and lower X-axis linear guides 31 are joined to beam member 21 by, for example, a combination of bonding and screw joining or pin joining. In addition, Y-axis block members 22 made of aluminum or an aluminum alloy are fixed to both end portions of beam member 21, respectively, and beam member 21 moves in the front-rear direction (Y axis) by moving Y-axis block members 22 at both end portions on corresponding Y-axis linear guides 51, respectively.

In the present embodiment, X-axis linear guide 31 is formed to be hollow. Head 20 is supported by beam member 21 to be movable left and right along X-axis linear guide 31. Beam member 21 is made of CFRP or AFRP, X-axis linear guide 31 is formed hollow, and Y-axis block member 22 is made of aluminum or an aluminum alloy, so that it is possible to reduce the weight of these members, and beam member 21 can be moved at high speed. In addition, by forming beam member 21 in a simple rectangular tubular shape, it is possible to facilitate processing with CFRP or AFRP and reduce manufacturing cost.

First X-axis moving device 30a moves first head 20a to the left-right direction (X axis). Second X-axis moving device 30b moves second head 20b to the left-right direction (X axis). As illustrated in FIGS. 3 and 4, first and second X-axis moving devices 30a and 30b (X-axis moving device 30) include pair of upper and lower X-axis linear guides 31 described above, X-axis linear motor 32, multiple (four) X-axis guide nuts 36, X-axis linear scale 38 (refer to FIG. 5), and X-axis cooling device 40.

As illustrated in FIG. 1, X-axis linear motor 32 of first X-axis moving device 30a operates by receiving electric power supply via a first X-axis power cable supported by first X-axis cableveyor (Cableveyor is a registered trademark) 16a. A first end of first X-axis cableveyor 16a is fixed to first beam member 21a and a second end of first X-axis cableveyor 16a is fixed to first head 20a so that first X-axis cableveyor 16a extends in the left-right direction (X axis) and follows the movement of first head 20a in the left-right direction. In addition, X-axis linear motor 32 of second X-axis moving device 30b operates by receiving electric power supply via a second X-axis power cable supported by second X-axis cableveyor 16b. A first end of second X-axis cableveyor 16b is fixed to second beam member 21b and a second end of second X-axis cableveyor 16b is fixed to second head 20b so that second X-axis cableveyor 16b extends in the left-right direction (X axis) and follows the movement of second head 20b in the left-right direction.

In the present embodiment, X-axis linear motor 32 is configured as a flat type linear motor including X-axis stator 33 attached to a side surface of beam member 21 and X-axis mover 34 disposed to face X-axis stator 33 at a predetermined interval in the front-rear direction. X-axis stator 33 has multiple permanent magnets arranged between pair of upper and lower X-axis linear guides 31 on the side surface of beam member 21 such that polarities of the N poles and the S poles are alternately different along X-axis linear guides 31. X-axis mover 34 includes 3×n cores (n is a natural number, for example, a value of 3) each formed by laminating electromagnetic steel plates, and 3×n coils each wound around the corresponding cores. X-axis mover 34 is supported by X-axis guide nuts 36, which are disposed on pair of upper and lower X-axis linear guides 31, respectively, and moves to the left-right direction (X axis) by applying a three-phase alternating current to the 3×n coils. As illustrated in FIGS. 3 and 6, in the present embodiment, two X-axis guide nuts 36 are disposed on each of pair of upper and lower X-axis linear guides 31, and X-axis mover 34 is supported by a total of four X-axis guide nuts 36.

As illustrated in FIG. 5, X-axis linear scale 38 is disposed on the bottom surface of beam member 21 to extend in the left-right direction. Sensor 39 is directly or indirectly attached to head 20, and sensor 39 detects the position of head 20 in the left-right direction (X axis) by reading X-axis linear scale 38.

In addition, as illustrated in FIG. 4, X-axis cooling device 40 is interposed between head 20 and X-axis mover 34. X-axis cooling device 40 radiates heat generated by energizing the coil of X-axis mover 34 by heat exchange with air. As illustrated in FIGS. 6 and 7, the surface of X-axis mover 34 is formed with multiple grooves 34r extending in the up-down direction in parallel with each other at predetermined intervals. Each groove 34r forms an air flow path in a state where X-axis cooling device 40 is attached to X-axis mover 34. X-axis cooling device 40 includes air inlet portion 41 connected to an air supply source (not illustrated) and formed on a first end side of multiple air flow paths (grooves 34r), air outlet portion 42 formed on a second end side of multiple air flow paths, and distribution section 43 that distributes air input from air inlet portion 41 to multiple air flow paths. Air outlet portions 42 are provided at two locations on the left and right sides, and the air passing through the air flow path is divided into the left and right sides and discharged from respective air outlet portions 42. Accordingly, X-axis cooling device 40 can efficiently cool X-axis mover 34 by air cooling, and can make the device more compact and reduce the cost as compared with a device that cools X-axis mover 34 by water cooling or cooling by a conventional heat pipe, a heat sink, and a cooling fan.

First Y-axis moving device 50a moves first beam member 21a in the front-rear direction (Y axis). Second Y-axis moving device 50b moves second beam member 21b in the front-rear direction (Y axis). As illustrated in FIGS. 2, 8, and 9, first and second Y-axis moving devices 50a and 50b (Y-axis moving device 50) include pair of left and right Y-axis linear guides 51, Y-axis linear motors 52 provided on the left and right sides, respectively, multiple Y-axis guide nuts 56 that are slidably mounted on pair of left and right Y-axis linear guides 51 and that support Y-axis block member 22, Y-axis linear scale 58 (refer to FIG. 5), and Y-axis cooling device 60.

As illustrated in FIG. 1, Y-axis linear motors 52 on the left and right sides of first Y-axis moving device 50a operate by receiving a supply of electric power through a first Y-axis power cable supported by first Y-axis cableveyor 17a. First Y-axis cableveyor 17a is installed above Y-axis linear guide 51 on the right side of pair of left and right Y-axis linear guides 51. Then, a first end of first Y-axis cableveyor 17a is disposed substantially in the center in the front-rear direction and is fixed to a power box (not illustrated) on the right side to which the first Y-axis power cable is connected, and a second end is fixed to Y-axis block member 22 on the right side of first beam member 21a to extend in the front-rear direction and follow the movement of first beam member 21a in the front-rear direction. The first Y-axis power cable extends from Y-axis block member 22 on the right side to Y-axis block member 22 on the left side through the inside of first beam member 21a, and supplies electric power to Y-axis linear motor 52 (Y-axis mover 54), which is fixed to Y-axis block member 22 on the right side, and Y-axis linear motor 52 (Y-axis mover 54) on the left side, which is fixed to Y-axis block member 22 on the left side.

In addition, Y-axis linear motors 52 on the left and right sides of second Y-axis moving device 50b operate by receiving electric power supply through a second Y-axis power cable supported by second Y-axis cableveyor 17b. Second Y-axis cableveyor 17b is installed above Y-axis linear guide 51 on the left side of pair of left and right Y-axis linear guides 51. Then, a first end of second Y-axis cableveyor 17b is disposed substantially in the center in the front-rear direction and is fixed to a power box (not illustrated) on the left side to which the second Y-axis power cable is connected, and a second end is fixed to Y-axis block member 22 on the left side of second beam member 21b to extend in the front-rear direction and follow the movement of second beam member 21b in the front-rear direction. The second Y-axis power cable extends from Y-axis block member 22 on the left side to Y-axis block member 22 on the right side through the inside of second beam member 21b, and supplies electric power to Y-axis linear motor 52 (Y-axis mover 54) on the left side, which is fixed to Y-axis block member 22 on the left side, and Y-axis linear motor 52 (Y-axis mover 54) on the right side, which is fixed to Y-axis block member 22 on the right side.

As described above, in the present embodiment, since first Y-axis cableveyor 17a is disposed on the left side and second Y-axis cableveyor 17b is disposed on the right side, it is possible to prevent first Y-axis cableveyor 17a and second Y-axis cableveyor 17b from interfering with each other when first and second heads 20a and 20b sharing pair of left and right Y-axis linear guides 51 are moved.

As illustrated in FIG. 2, pair of left and right Y-axis linear guides 51 are disposed on the upper surfaces of support tables 13 on the left and right sides to extend in the front-rear direction.

As illustrated in FIGS. 8 and 9, Y-axis linear motor 52 is a flat-type linear motor including Y-axis stator 53 fixed to support table 13 to extend in the front-rear direction and Y-axis mover 54 fixed to Y-axis block member 22 to face Y-axis stator 53 at a predetermined interval in the up-down direction. Y-axis stator 53 has multiple permanent magnets disposed in a flat manner on the same plane as Y-axis linear guide 51 such that the polarities of the N poles and the S poles are alternately different along Y-axis linear guide 51. In the present embodiment, the permanent magnets of Y-axis stator 53 are the same as the permanent magnets of X-axis stator 33. The cost can be reduced by sharing the components. Y-axis mover 54 includes 3×m (m is a natural number, for example, a value of 5) cores formed by laminating electromagnetic steel plates, and 3×m coils each wound around the corresponding cores. Y-axis mover 54 moves in the front-rear direction (Y axis) by applying three-phase alternating currents to the 3×m coils.

As illustrated in FIG. 9, three Y-axis guide nuts 56 are mounted to each of pair of left and right Y-axis linear guides 51. Y-axis block members 22 fixed to both end portions of beam member 21 are fixed to the upper surfaces of three Y-axis guide nuts 56, respectively. Accordingly, the load applied to Y-axis block member 22 by the attractive force of Y-axis linear motor 52 can be distributed almost uniformly to three Y-axis guide nuts 56, and the movement of beam member 21 can be stabilized by reducing the gap change between Y-axis stator 53 and Y-axis mover 54 by the attractive force and the durability of Y-axis linear guide 51 and Y-axis guide nut 56 can be improved.

As illustrated in FIG. 5, Y-axis linear scales 58 are disposed on the side surfaces of support tables 13 on the left and right sides facing each other to extend in the front-rear direction. Sensor 59 is directly or indirectly attached to beam member 21, and sensor 59 reads Y-axis linear scale 58 to detect the position of head 20 (beam member 21) in the front-rear (Y axis) direction.

In addition, as illustrated in FIGS. 8 and 9, Y-axis cooling device 60 is interposed between Y-axis block member 22 and Y-axis mover 54. Y-axis cooling device 60 radiates heat generated by energizing the coil of Y-axis mover 54 by heat exchange with air. As illustrated in FIGS. 10 and 11, the surface of Y-axis mover 54 on Y-axis block member 22 side is formed with multiple grooves 54r extending in the left-right direction in parallel to each other. Each groove 54r forms an air flow path in a state where Y-axis cooling device 60 is attached to Y-axis mover 54. Y-axis cooling device 60 includes air inlet portion 61 connected to an air supply source (not illustrated) and formed on a first end side of multiple air flow paths (grooves 54r), air outlet portion 62 formed on a second end side of multiple air flow paths, and distribution section 63 that distributes air input from air inlet portion 61 to multiple air flow paths. Air inlet portions 61 are provided at four locations at intervals in the left-right direction. Air outlet portions 62 are provided at two locations on the left and right sides, and the air passing through the air flow path is divided into the left and right sides and discharged from respective air outlet portions 62. Accordingly, Y-axis cooling device 60 can efficiently cool Y-axis mover 54 by air cooling, and can make the device more compact and reduce the cost as compared with a device that cools Y-axis mover 54 by water cooling or cooling by a conventional heat pipe, a heat sink, and a cooling fan.

Furthermore, multiple grooves 60r extending in the front-rear direction in parallel with each other are formed on the upper surface of case 60c of Y-axis cooling device 60, intake fan 66 is installed as needed on a first end side in the front-rear direction of the upper surface of case 60c, and exhaust fan 67 is installed as needed on a second end side in the front-rear direction. Groove 60r forms an air flow path in a state where the upper surface of case 60c and Y-axis block member 22 are joined. Air drawn in by intake fan 66 passes through an air passage formed on the upper surface of case 60c, exchanges heat with the heat transferred from Y-axis mover 54 to case 60c of Y-axis cooling device 60, and is discharged from exhaust fan 67.

In addition, as illustrated in FIG. 1, exhaust fans 15 are installed at four corners of an upper portion of housing 11. Each of exhaust fans 15 discharges the air in the device including the air discharged from each of X-axis cooling devices 40 and each of Y-axis cooling devices 60 to the outside of the device.

Here, the correspondence relationship between the constituent elements of the embodiment and the constituent elements of the present disclosure described in the scope of the claims will be clarified. Head 20 (first head 20a, second head 20b) of the embodiment corresponds to a head, pair of left and right Y-axis linear guides 51 correspond to a pair of first axis linear guides, beam member 21 (first beam member 21a, second beam member 21b) corresponds to a beam member, and pair of upper and lower X-axis linear guides 31 correspond to a pair of second axis linear guides. In addition, Y-axis block member 22 corresponds to a first axis block member, Y-axis stator 53 corresponds to a first axis stator, Y-axis mover 54 corresponds to a first axis mover, and Y-axis linear motor 52 corresponds to a first axis linear motor. Three Y-axis guide nuts 56 correspond to three guide nuts. X-axis linear scale 38 corresponds to a linear scale. First head 20a corresponds to a first head, second head 20b corresponds to a second head, first beam member 21a corresponds to a first beam member, second beam member 21b corresponds to a second beam member, first Y-axis moving device 50a corresponds to a first first-axis moving device, second Y-axis moving device 50b corresponds to a second first-axis moving device, first Y-axis cableveyor 17a corresponds to a first cableveyor, and second Y-axis cableveyor 21b corresponds to a second cableveyor. In addition, pair of Y-axis block members 22 correspond to a pair of first axis block members, pair of Y-axis linear motors 52 correspond to a pair of first axis linear motors, and Y-axis cooling device 60 corresponds to a first axis cooling member. In addition, X-axis linear motor 32 corresponds to a second axis linear motor, and X-axis cooling device 40 corresponds to a second axis cooling member.

It is needless to say that the present disclosure is not limited in any way to the above-described embodiment, and the present disclosure can be embodied in various aspects as long as the aspects fall within the technical scope of the present disclosure.

For example, in the above-described embodiment, component mounting machine 10 includes two heads 20 (first and second heads 20a and 20b), but may include a single head. In this case, component mounting machine 10 may include one beam member 21, one X-axis moving device 30, and one Y-axis moving device 50.

As described above, in the component mounting machine of the present disclosure, the beam member is made of carbon fiber reinforced plastic or aramid fiber reinforced plastic in a rectangular tubular shape. Accordingly, weight reduction can be achieved while ensuring rigidity. As a result, it is possible to further speed up the movement of the head. Furthermore, since the simple shape facilitates processing, the manufacturing cost can be reduced.

In addition, the component mounting machine of the present disclosure can also adopt the following configuration. That is, the component mounting machine of the present disclosure may include a pair of first axis block members each made of aluminum or an aluminum alloy and configured to move on a corresponding first axis linear guide of the pair of first axis linear guides and support a corresponding end portion of the beam member, and a pair of first axis linear motors each including a first axis stator extending along a corresponding first axis linear guide and a first axis mover fixed to a corresponding first axis block member to face the first axis stator at a predetermined interval. With this configuration, the beam member can be smoothly moved to the first axis by synchronously driving the pair of first axis linear motors.

Furthermore, in the component mounting machine of the present disclosure, the pair of second axis linear guides may be hollow rails. With this configuration, it is possible to further reduce the weight of the beam member.

In addition, the component mounting machine of the present disclosure may include at least three guide nuts each disposed to be slidable on a corresponding first axis linear guide of the pair of first axis linear guides, and a pair of first axis block members each fixed to upper surfaces of corresponding at least three guide nuts and configured to support a corresponding end portion of the beam member. With this configuration, the load applied to the first axis block member can be distributed to the three guide nuts, and the movement of the beam member can be stabilized and durability of the first axis linear guide or the guide nut can be improved.

In addition, the component mounting machine of the present disclosure may include a linear scale disposed on the beam member to extend in the second axis direction, and the linear scale may be disposed outside between the pair of second axis linear guides. With this configuration, the beam member can be made more compact as compared with a beam member in which the linear scale is disposed inside between the pair of second axis linear guides.

In addition, the component mounting machine of the present disclosure may include a first axis moving device configured to move the beam member in the first axis direction, and the head may include a first head and a second head, the beam member may include a first beam member that is movable in the first axis direction on the pair of first axis linear guides and supports the first head to be movable in the second axis direction, and a second beam member that shares the pair of first axis linear guides with the first beam member, is movable in the first axis direction independently of the first beam member, and supports the second head to be movable in the second axis direction, the first axis moving device may include a first first-axis moving device configured to move the first beam member in the first axis direction by electric power supplied through a cable supported by a first cableveyor, and a second first-axis moving device configured to move the second beam member in the first axis direction by electric power supplied through a cable supported by a second cableveyor, the first cableveyor may be disposed on a first side of the pair of first axis linear guides, and the second cableveyor may be disposed on a second side of the pair of first axis linear guides. With this configuration, it is possible to prevent the first and second cableveyors from interfering with each other when the first and second heads sharing the pair of first axis linear guides are moved.

In addition, the component mounting machine of the present disclosure may include a pair of first axis block members each configured to move on a corresponding first axis linear guide of the pair of first axis linear guides and support a corresponding end portion of the beam member, a pair of first axis linear motors each including a first axis stator extending along a corresponding first axis linear guide and a first axis mover fixed to a corresponding first axis block member to face the first axis stator at a predetermined interval, and a first axis cooling member interposed between the first axis block member and the first axis mover and configured to cool the first axis mover by air. With this configuration, the device can be made more compact as compared with a device in which the first axis mover is cooled by water cooling.

In addition, the component mounting machine of the present disclosure may include a second axis linear motor including a second axis stator that is disposed on the beam member to extend along the pair of second axis linear guides and a second axis mover that is supported by the pair of second axis linear guides to face the second axis stator at a predetermined interval and that supports the head, and a second axis cooling member interposed between the head and the second axis mover and configured to cool the second axis mover by air. With this configuration, the device can be made more compact as compared with a device in which the second axis mover is cooled by water cooling.

### INDUSTRIAL APPLICABILITY

The present disclosure can be used for a manufacturing industry of component mounting machines, and the like.

### REFERENCE SIGNS LIST

10: component mounting machine, 11: housing, 12: base, 13: support table, 14: operation panel, 15: exhaust fan, 16a: first X-axis cableveyor, 16b: second X-axis cableveyor, 17a: first Y-axis cableveyor, 17b: second Y-axis cableveyor, 20: head, 20a: first head, 20b: second head, 21: beam member, 21a: first beam member, 21b: second beam member, 22: Y-axis block member, 30: X-axis moving device, 30a: first X-axis moving device, 30b: second X-axis moving device, 31: X-axis linear guide, 32: X-axis linear motor, 33: X-axis stator, 34: X-axis mover, 34r: groove, 36: X-axis guide nut, 38: X-axis linear scale, 39: sensor, 40: X-axis cooling device, 41: air inlet portion, 42: air outlet portion, 43: distribution section, 50: Y-axis moving device, 50a: first Y-axis moving device, 50b: second Y-axis moving device, 51: Y-axis linear guide, 52: Y-axis linear motor, 53: Y-axis stator, 54: Y-axis mover, 54r: groove, 56: Y-axis guide nut, 58: Y-axis linear scale, 59: sensor, 60: Y-axis cooling device, 60c: case, 60r: groove, 61: air inlet portion, 62: air outlet portion, 63: distribution section, 66: intake fan, 67: exhaust fan, F: feeder, S: board

1. A component mounting machine for mounting a component, comprising:
a head configured to pick up the component;
a pair of first axis linear guides configured to extend in a first axis direction;
a beam member made of carbon fiber reinforced plastic or aramid fiber reinforced plastic in a rectangular tubular shape to extend in a second axis direction intersecting the first axis, having both end portions bridged between the pair of first axis linear guides, and configured to move in the first axis direction; and
a pair of second axis linear guides disposed on the beam member to extend in the second axis direction and configured to guide the head movably in the second axis direction.

2. The component mounting machine according to claim 1, further comprising:
a pair of first axis block members each made of aluminum or an aluminum alloy and configured to move on a corresponding first axis linear guide of the pair of first axis linear guides and support a corresponding end portion of the beam member; and
a pair of first axis linear motors each including a first axis stator extending along a corresponding first axis linear guide and a first axis mover fixed to a corresponding first axis block member to face the first axis stator at a predetermined interval.

3. The component mounting machine according to claim 1,
wherein the pair of second axis linear guides are hollow rails.

4. The component mounting machine according to claim 1, further comprising:
at least three guide nuts each disposed to be slidable on a corresponding first axis linear guide of the pair of first axis linear guides; and
a pair of first axis block members each fixed to upper surfaces of corresponding at least three guide nuts and configured to support a corresponding end portion of the beam member.

5. The component mounting machine according to claim 1, further comprising:
a linear scale disposed on the beam member to extend in the second axis direction,
wherein the linear scale is disposed outside between the pair of second axis linear guides.

6. The component mounting machine according to claim 1, further comprising:
a first axis moving device configured to move the beam member in the first axis direction,
wherein the head includes a first head and a second head,
the beam member includes a first beam member that is movable in the first axis direction on the pair of first axis linear guides and supports the first head to be movable in the second axis direction, and a second beam member that shares the pair of first axis linear guides with the first beam member, is movable in the first axis direction independently of the first beam member, and supports the second head to be movable in the second axis direction,
the first axis moving device includes a first first-axis moving device configured to move the first beam member in the first axis direction by electric power supplied through a cable supported by a first cableveyor (cableveyor is a registered trademark), and a second first-axis moving device configured to move the second beam member in the first axis direction by electric power supplied through a cable supported by a second cableveyor,
the first cableveyor is disposed on a first side of the pair of first axis linear guides, and
the second cableveyor is disposed on a second side of the pair of first axis linear guides.

7. The component mounting machine according to claim 1, further comprising:
a pair of first axis block members each configured to move on a corresponding first axis linear guide of the pair of first axis linear guides and support a corresponding end portion of the beam member;
a pair of first axis linear motors each including a first axis stator extending along a corresponding first axis linear guide and a first axis mover fixed to a corresponding first axis block member to face the first axis stator at a predetermined interval; and
a first axis cooling member interposed between the first axis block member and the first axis mover and configured to cool the first axis mover by air.

8. The component mounting machine according to claim 1, further comprising:
a second axis linear motor including a second axis stator that is disposed on the beam member to extend along the pair of second axis linear guides and a second axis mover that is supported by the pair of second axis linear guides to face the second axis stator at a predetermined interval and that supports the head; and
a second axis cooling member interposed between the head and the second axis mover and configured to cool the second axis mover by air.
